(19) United States
(12) Patent Application Publication
(10) Pub. No.: US 2025/0210237 A1
(43) Pub. Date: Jun. 26, 2025

(54) COIL COMPONENT AND IC CARD HAVING THE SAME

(71) Applicant: TDK Corporation, Tokyo (JP)

(72) Inventors: Ryota UCHIYAMA, Tokyo (JP); Yoshitomo SATO, Tokyo (JP); Daiki INOUE, Tokyo (JP); Toshio TOMONARI, Tokyo (JP)

(73) Assignee: TDK Corporation, Tokyo (JP)

(21) Appl. No.: 19/000,769

(22) Filed: Dec. 24, 2024

(30) Foreign Application Priority Data
Dec. 24, 2023 (JP) 2023-217493

(51) Int. Cl. H01F 5/06; H01F 1/10; H01F 17/04; H01L 23/64

(52) U.S. Cl. CPC H01F 5/06; H01F 1/10; H01F 17/04; H01L 23/645; H01F 2017/048

(57) ABSTRACT

Disclosed herein is a coil component that includes: a coil pattern having a seed part including resin and having first and second surfaces positioned on mutually opposite sides, and a main body part made of a metal material and laminated on the second surface of the seed part; a magnetic body covering the coil pattern; and a first resin layer positioned between the coil pattern and magnetic body and including spherical filler particles and binder resin. The coil pattern is embedded in the first resin layer such that the first surface of the seed part is exposed from the first resin layer.

### CROSS-REFERENCE TO RELATED APPLICATION

This application claims the benefit of Japanese Patent Application No. 2023-217493, filed on Dec. 24, 2023, the entire disclosure of which is incorporated by reference herein.

### BACKGROUND

The present disclosure relates to a coil component and an IC card having the same.

JP 2019-161152A discloses a configuration in which a wiring forming a coil pattern is covered with a magnetic layer containing magnetic particles.

The magnetic particles described in JP 2019-161152A have a flat shape, so that when the aspect ratio thereof is increased so as to enhance magnetic characteristics, the magnetic layer fails to follow irregularities on an insulating layer due to wiring, with the result that voids occur disadvantageously around wirings.

### SUMMARY

The present disclosure describes a technology for preventing, in a coil component including a coil pattern and a magnetic body covering the coil pattern, voids from occurring around a coil pattern.

A coil component according to an embodiment of the present disclosure includes: a coil pattern having a seed part including resin and having first and second surfaces positioned on mutually opposite sides, and a main body part made of a metal material and laminated on the second surface of the seed part; a magnetic body covering the coil pattern; and a first resin layer positioned between the coil pattern and magnetic body and including spherical filler particles and binder resin. The coil pattern is embedded in the first resin layer such that the first surface of the seed part is exposed from the first resin layer.

### BRIEF DESCRIPTION OF THE DRAWINGS

The above features and advantages of the present disclosure will be more apparent from the following description of certain embodiments taken in conjunction with the accompanying drawings, in which:

FIG. 1 is a schematic perspective view illustrating the outer appearance of an IC card 2 having a coil component according to an embodiment of the present disclosure;

FIG. 2 is a schematic exploded perspective view for explaining the structure of the IC card 2 having a coil component 1;

FIG. 3 is a schematic cross-sectional view for explaining the structure of the IC card 2 having a coil component 1;

FIG. 4 is a partial cross-sectional view of the coil component 1;

FIG. 5 is a partial cross-sectional view of a coil component 1A according to a first modification;

FIG. 6 is a partial cross-sectional view of a coil component 1B according to a second modification;

FIG. 7 is a partial cross-sectional view of a coil component 1C according to a third modification; and

FIG. 8 is a partial cross-sectional view of a coil component 1D according to a fourth modification.

### DETAILED DESCRIPTION OF THE EMBODIMENTS

Some embodiments of the present disclosure will be explained below in detail with reference to the accompanying drawings.

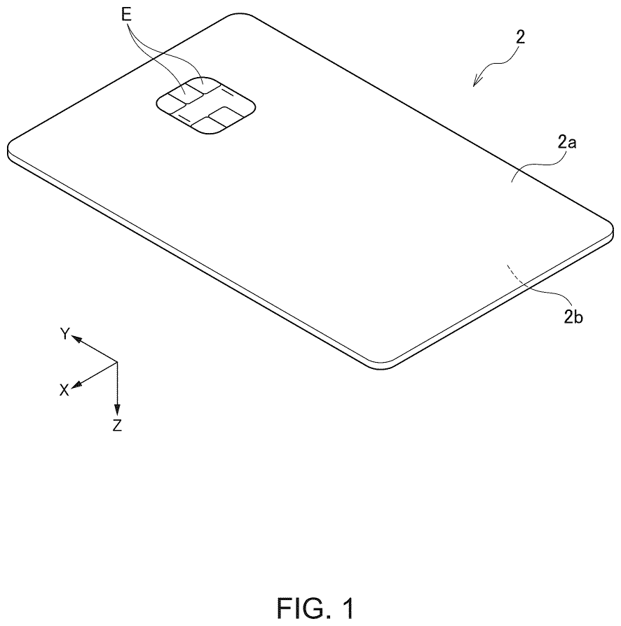

FIG. 1 is a schematic perspective view illustrating the outer appearance of an IC card 2 having a coil component according to an embodiment of the present disclosure.

As illustrated in FIG. 1, the IC card 2 according to the present embodiment has a plate-like body in which the Y-, X-, and Z-directions thereof are respectively defined as the longer side direction, shorter side direction, and thickness direction and has an upper surface 2a and a back surface 2b which constitute the XY plane. The IC card 2 incorporates therein an IC module to be described later, and a terminal electrode E of the IC module is exposed to the upper surface 2a of the IC card 2.

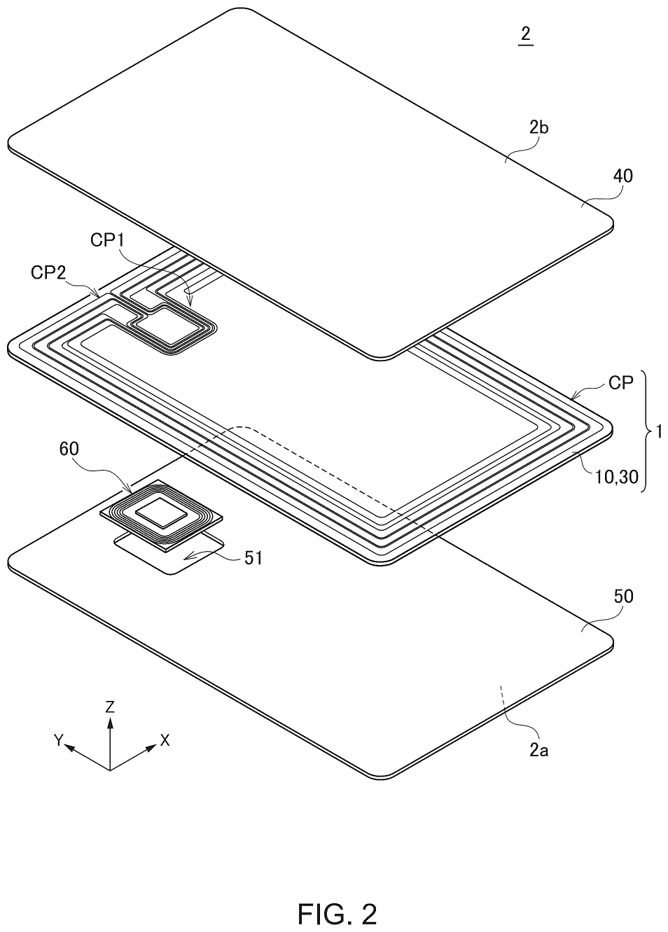

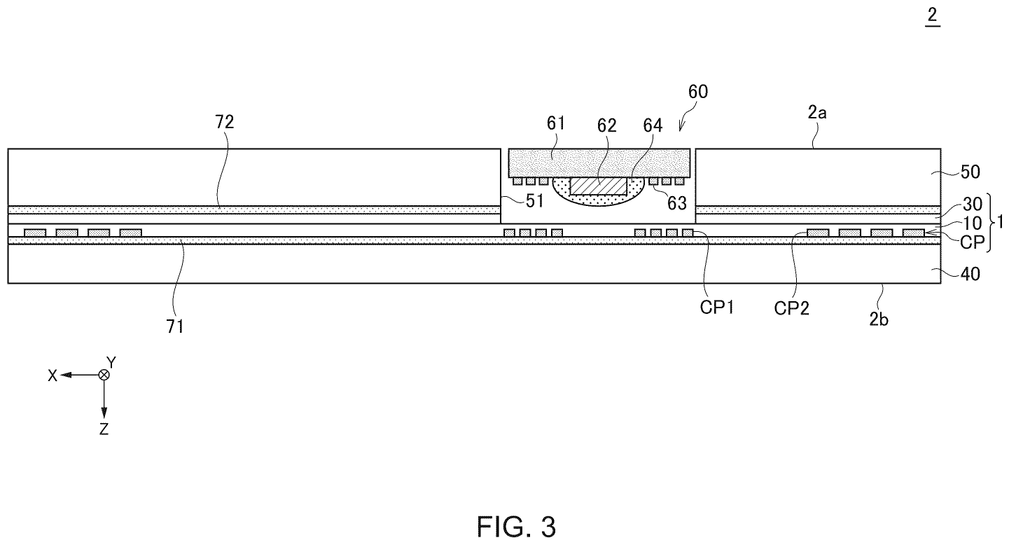

FIGS. 2 and 3 are respectively a schematic exploded perspective view and a schematic cross-sectional view for explaining the structure of the IC card 2 having a coil component 1 according to the present embodiment.

The IC card 2 illustrated in FIGS. 2 and 3 has a structure in which a plastic plate 40, the coil component 1, and a metal plate 50 are laminated in this order from the back surface 2b side to the upper surface 2a side. The coil component 1 according to the present embodiment includes a coil pattern CP, a first resin layer 10, and a magnetic body 30. The plastic plate 40 and coil component 1 are bonded to each other through an adhesive layer 71. The metal plate 50 and coil component 1 are bonded to each other through an adhesive layer 72. Examples of the material of the adhesive layers 71 and 72 include an acrylic-based double-sided tape, a thermosetting resin, and a thermoplastic resin.

The plastic plate 40 is made of a resin material not blocking magnetic flux. The outer surface of the plastic plate 40 constitutes the back surface 2b of the IC card 2. The metal plate 50 is made of a metal material such as stainless steel or titanium. The outer surface of the metal plate 50 constitutes the upper surface 2a of the IC card 2. The metal plate 50 has a through hole 51 inside of which an IC module 60 is disposed. As described above, the IC card 2 is a card using a metal plate as its main body.

The IC module 60 includes a module substrate 61, an IC chip 52 mounted on or incorporated in the module substrate 61, and a coupling coil 63. The IC chip 62 is protected by being covered with a dome-shaped protective resin 54. The terminal electrode E illustrated in FIG. 1 is provided on the surface of the module substrate 61 on the opposite side of the surface on which the IC chip 62 is mounted. The IC module 60 thus configured is electromagnetically coupled to a coupling coil CP1 constituting a part of the coil pattern CP. This allows communication between an external card reader and IC chip 62 through an antenna coil CP2 which is another part of the coil pattern CP

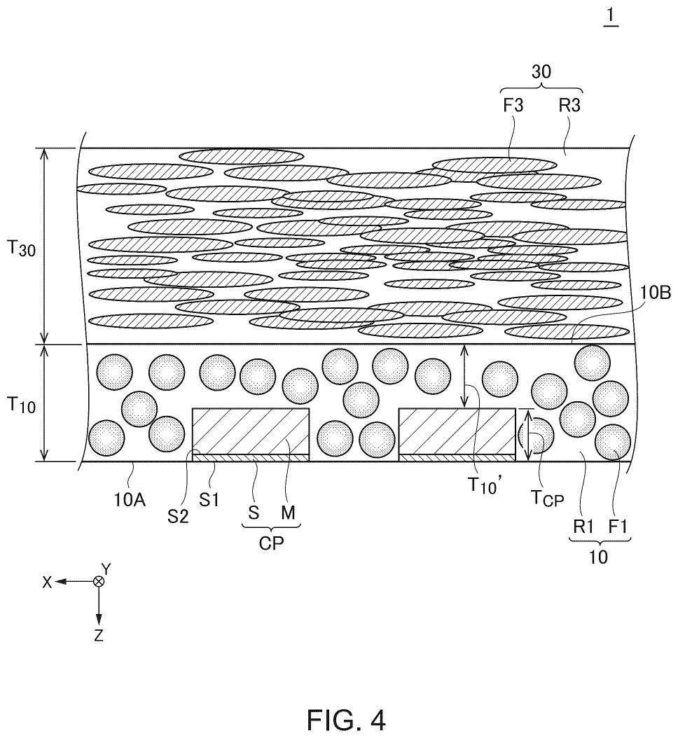

FIG. 4 is a partial cross-sectional view of the coil component 1.

As illustrated in FIG. 4, the coil pattern CP is embedded in the first resin layer 10 so as to be partially exposed from a surface 10A of the first resin layer 10. The coil pattern CP includes a seed part S and a main body part M. The seed part S contains resin and has first and second surfaces S1 and S2. The main body part M is made of a metal material and laminated on the second surface S2 of the seed part S. The first surface S1 of the seed part is exposed from the first resin layer 10. The first and second surfaces S1 and S2 are positioned on mutually opposite sides. Although the coil pattern CP is formed on the surface of a not illustrated substrate, the substrate may be detached afterward from the coil pattern CP. In this case, the substrate is not included in the coil component 1. This reduces the thickness of the coil component 1 in the Z-direction. The Z-direction is the coil axis direction of the coil pattern CP and also the thickness direction thereof. Alternatively, the substrate may be left without being detached. In this case, the first surface S1 of the seed part S is included in the substrate used to form the coil pattern CP.

The coil pattern CP is embedded in the first resin layer 10 such that the first surface S1 of the seed part S is exposed from the surface 10A of the first resin layer 10. The metal material constituting the main body part M of the coil pattern CP may be Cu. The seed part S may contain a material functioning as a catalyst when the main body part M is formed by plating. The thickness of the main body part M may be larger than the thickness of the seed part S. This can reduce the resistance value of the coil pattern CP.

The main body part M may completely be embedded in the first resin layer 10 without being exposed therefrom. Alternatively, only a part of the main body part M, for example, a part that covers the side surface of the seed part S may be exposed from the first resin layer 10. In the example illustrated in FIG. 4, the seed part S is also embedded in the first resin layer 10, and the surface 10A of the first resin layer 10 and first surface S1 of the seed part S are flush with each other.

The first resin layer 10 is sandwiched in the Z-direction between the coil pattern CP and magnetic body 30. The first resin layer 10 contains spherical filler particles F1 and binder resin R1. A thickness T₁₀ of the first resin layer 10 in the Z-direction is 30 μm to 50 μm, for example. A surface 10B of the first resin layer 10 on the side contacting the magnetic body 30 is substantially flat and, accordingly, the thickness of the first resin layer 10 is reduced at a portion where the coil pattern CP is present. A thickness T_{10′} of the first resin layer 10 at a portion between the coil pattern CP and magnetic body 30 has a value obtained by subtracting a thickness T_{CP} of the coil pattern CP from the thickness T₁₀. For example, the thickness T_{CP} of the coil pattern CP is 10 μm to 30 μm.

The filler particles F1 have a spherical shape. By using such spherical filler particles F1, it is possible to make voids unlikely to occur around the coil pattern CP while increasing the strength of the first resin layer 10. The material of the filler particles F1 may be a nonmagnetic inorganic material, such as aluminum, or a magnetic material such as ferrite or an Fe-based alloy magnetic body. Examples of the Fe-based alloy magnetic body include permalloy, sendust, Fe—Si—Cr, Fe—Si, carbonyl iron, Fe-based alloy amorphous powder containing at least Fe—Si—B, and Fe-based alloy nanocrystalline powder containing at least Fe—B—P—Cu. When a magnetic material is used for the filler particles F1, the inductance of the coil pattern CP can be increased. The average particle diameter (D₅₀) of the filler particles F1 is 2 μm to 10 μm, for example. The average particle diameter is a value of D50 which is a value obtained in laser diffraction particle distribution measurement.

Examples of the material of the binder resin R1 include acrylic resin, polyester resin, polyethylene resin, polyvinyl chloride resin, polyvinyl butyral resin, poly urethane resin, polyester urethane resin, cellulose resin, ABS (acrylonitrile-butadiene-styrene) resin, nitrile-butadiene rubber, styrene-butadiene rubber, epoxy resin, phenol resin, amide resin, polyester elastomer, and polyamide elastomer. The elongation percentage obtained by tensile test for resin used as the binder resin R1 may be higher than 400%.

The thickness T_{10′} of the first resin layer 10 between the coil pattern CP and magnetic body 30 can be made smaller as the average particle diameter (D₅₀) of the filler particles F1 becomes smaller. This makes it possible to disperse the filler particles F1 more uniformly while maintaining a sufficient filling rate of the filler particles F1 in the first resin layer 10. For example, in a case where the average particle diameter (D₅₀) of the filler particles F1 is less than 5 μm, even when the thickness T_{10′} of the first resin layer 10 between the coil pattern CP and magnetic body 30 is set smaller than the thickness T_{CP} of the coil pattern CP, it is possible to disperse the filler particles F1 uniformly while maintaining a sufficient filling rate of the filler particles F1 in the first resin layer 10, thus allowing further reduction in the entire thickness of the coil component 1 and reduction in the distance between the coil pattern CP and magnetic body 30. On the other hand, in a case where the average particle diameter (D₅₀) of the filler particles F1 is equal to or more than 5 μm, by setting the thickness T_{10′} of the first resin layer 10 between the coil pattern CP and magnetic body 30 larger than the thickness T_{CP} of the coil pattern CP, it is possible to disperse the filler particles F1 uniformly while maintaining a sufficient filling rate of the filler particles F1 in the first resin layer 10.

The magnetic body 30 is used for preventing application of magnetic flux to the metal plate 50 by covering the antenna coil CP2 constituting a part of the coil pattern CP. The magnetic body 30 cannot be provided at a position overlapping the coupling coil CP1, that is, at a position overlapping the through hole 51 of the metal plate 50. A thickness T₃₀ of the magnetic body 30 in the Z-direction is 50 μm, for example. The thickness T₃₀ of the magnetic body 30 may be larger than the thickness T₁₀ of the first resin layer 10. This increases the inductance of the coil pattern CP.

The magnetic body 30 may be a magnetic resin layer containing flat magnetic powders F3 and binder resin R3. The flat magnetic powders F3 may be made of a metal magnetic material such as sendust, permalloy, Fe—Si—Cr-based alloy magnetic body, Fe—Si—Al—Cr-based alloy magnetic body, or Fe—Al—Cr-based alloy magnetic body. The thickness direction of the flat magnetic powders F3 is the Z-direction, and the longer side direction thereof is the XY plane direction perpendicular to the Z-direction. The flat magnetic powders F3 are oriented such that the longer side direction thereof is substantially parallel to the XY plane direction. This increases the permeability of the magnetic body 30 in the XY plane direction. However, the longer side direction of all the flat magnetic powders F3 need not strictly be parallel to the XY plane direction, and the longer side direction of some flat magnetic powders F3 may have an inclination with respect to the XY plane direction. The size of the flat magnetic powders F3 in the XY plane direction may be larger than the thickness T₃₀ of the magnetic body 30 in the Z-direction. This further increases the permeability of the magnetic body 30 in the XY plane direction.

Examples of the material of the binder resin R3 include acrylic resin, polyester resin, polyethylene resin, polyvinyl chloride resin, polyvinyl butyral resin, poly urethane resin, polyester urethane resin, cellulose resin, ABS (acrylonitrile-butadiene-styrene) resin, nitrile-butadiene rubber, styrene-butadiene rubber, epoxy resin, phenol resin, amide resin, polyester elastomer, and polyamide elastomer. The resin material of the binder resin R3 may be the same as or different from that of the binder resin R1 contained in the first resin layer 10. The elongation percentage obtained by tensile test for resin used as the binder resin R3 may be higher than 400%. When the binder resin R1 contained in the first resin layer 10 and the binder resin R3 contained in the magnetic body 30 are made of the same resin material, adhesion between the first resin layer 10 and magnetic body 30 is enhanced. The binder resin R3 may be added with curing agent. Adding curing agent to the binder resin improves the heat resistance and moisture resistance of the magnetic body 30. When the magnetic body 30 is a magnetic resin layer containing the flat magnetic powders F3 and binder resin R3, the ratio (=F3/R3) of the flat magnetic powders F3 to the binder resin R3 may be about 4 to 8. This can enhance the permeability of the magnetic body 30. On the other hand, in the first resin layer 10, the ratio (=F1/R1) of the filler particles F1 to the binder resin R1 may be smaller than the value of F3/R3. This can enhance adhesion of the first resin layer 10 with respect to the coil pattern CP and magnetic body 10.

As described above, in the coil component 1 according to the present embodiment, the first resin layer 10 is provided between the coil pattern CP and magnetic body 30, so that when the aspect ratio of the flat magnetic powders F3 contained in the magnetic body 30 is high, voids are unlikely to occur around the coil pattern CP, making it possible to prevent peeling of the coil pattern CP. In addition, since the spherical filler particles F1 are contained in the first resin layer 10, it is possible to increase the strength of the first resin layer 10 while preventing occurrence of voids.

Further, as compared with when an adhesive sheet is used in place of the first resin layer 10, the entire thickness of the coil component 1 can be reduced. In the present embodiment, the substrate used to form the coil pattern CP is removed, so that the entire thickness of the coil component 1 is further reduced. Further, the entire or a large part of the main body part M of the coil pattern CP is not exposed from the surface 10A of the first resin layer 10, but only the seed part S is exposed therefrom, so that the main body part M of the coil pattern CP can be protected.

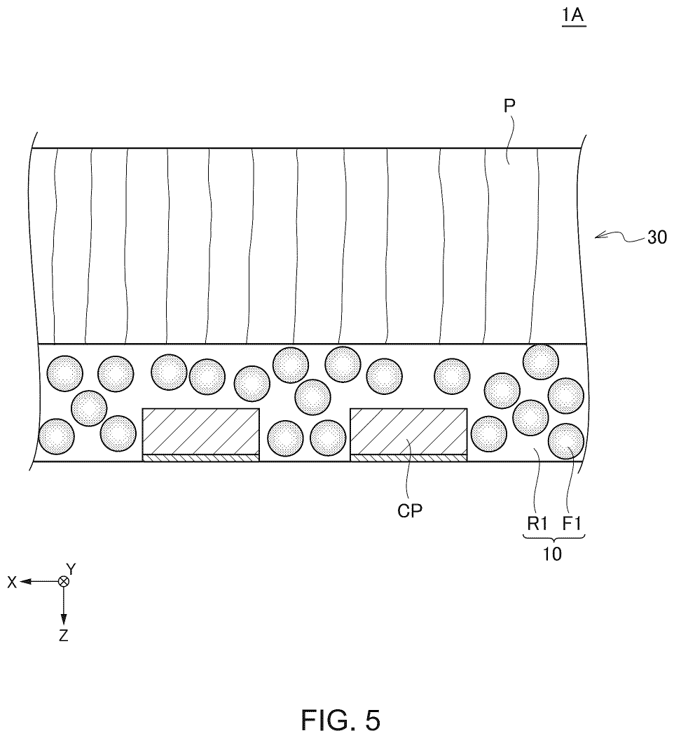

FIG. 5 is a partial cross-sectional view of a coil component 1A according to a first modification.

The coil component 1A according to the first modification illustrated in FIG. 5 differs from the coil component 1 illustrated in FIG. 4 in that the magnetic body 30 is formed of a ferrite sintered body. Other basic configurations are the same as those of the coil component 1 illustrated in FIG. 4, so the same reference numerals are given to the same elements, and overlapping description will be omitted.

As exemplified by the coil component 1A according to the first modification, the magnetic body 30 may be formed of a ferrite sintered body. This can increase the inductance of the coil pattern CP. The ferrite sintered body may be a collective body of a plurality of individual pieces P divided by gaps or cracks extending in the Z-direction. This can prevent breakage of the magnetic body 30 formed of the ferrite sintered body. The gaps or cracks need not extend strictly in the Z-direction. Further, some gaps or cracks may have an inclination with respect to the Z-direction and some may extend in the XY plane direction. The binder resin R1 constituting the first resin layer 10 may be infiltrated into the gaps or cracks between the individual pieces P of the ferrite sintered body. This allows the individual pieces P to be fixed to one another by the binder resin R1, making it possible to increase the strength of the magnetic body 30. The filtration of the binder resin R1 may be performed into only some of the plurality of gaps or cracks. Further, the filtration may be performed into only the first resin layer 10 side part of the gaps or cracks.

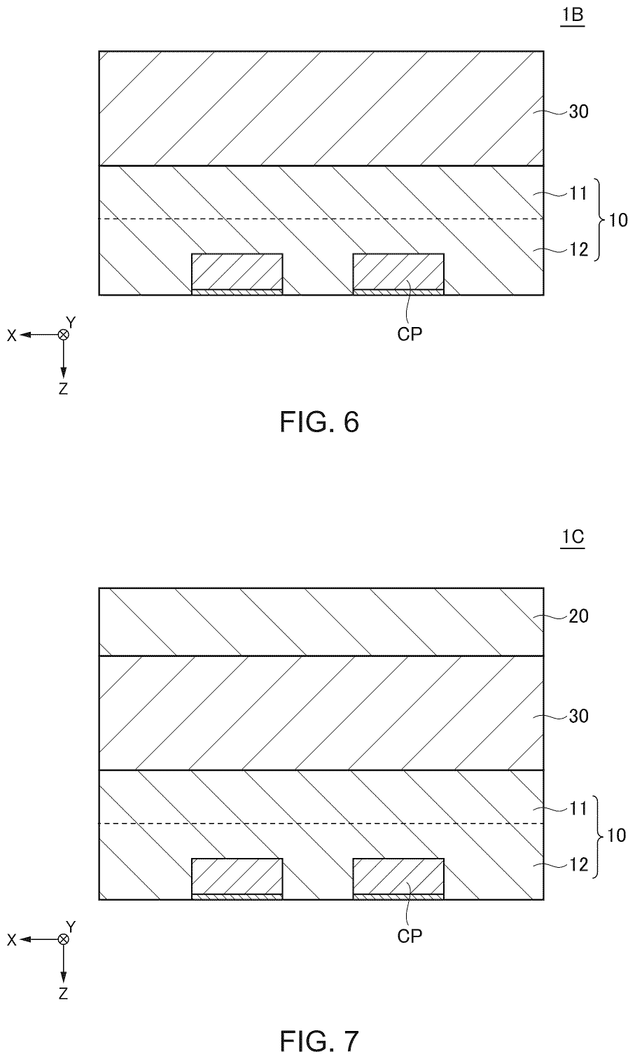

FIG. 6 is a partial cross-sectional view of a coil component 1B according to a second modification.

The coil component 1B according to the second modification illustrated in FIG. 6 differs from the coil component 1 illustrated in FIG. 4 in that the first resin layer 10 includes first and second regions 11 and 12. Other basic configurations are the same as those of the coil component 1 illustrated in FIG. 4, so the same reference numerals are given to the same elements, and overlapping description will be omitted.

The first region 11 is positioned on the magnetic body 30 side. The second region 12 is a region where the coil pattern CP is embedded and includes the surface 10A. The coil pattern CP may partially be embedded in the first region 11. The first and second regions 11 and 12 may be made of the same or different materials. When the first resin layer 10 is thus constituted by two regions, adhesion with respect to the coil pattern CP and magnetic body 30 is enhanced. The first and second regions 11 and 12 may be obtained by sectioning the first resin layer 10 of a single-layer configuration into two, or obtained by making the first resin layer 10 to have a two-layer configuration. The first resin layer 10 having a two-layer configuration can be formed by applying a first layer (first region 11) onto the surface of the magnetic body 30 and then applying a second layer (second region 12) onto the surface of the first layer (first region 11).

Alternatively, it may be possible to apply the second layer (second region 12) on the surface of the substrate (not illustrated) used to form the coil pattern CP and then to laminate the first layer (first region 11) having the magnetic body 30 thereon on the surface of the first layer (first region 11). In this case, if uncured curing agent is added to the binder resin R3 contained in the magnetic body 30, the curing agent may be infiltrated into the first layer (first region 11) serving as an underlying layer. Although this brings about a change in the characteristics of the first layer (first region 11), the curing agent does not reach the second layer (second region 12), so that the embedding characteristics for the coil pattern CP are not deteriorated. Further, the concentration of the curing agent contained in the first layer (first region 11) is lower than the concentration of the curing agent contained in the magnetic body 30 which is the magnetic resin layer, so that characteristics required for the first layer (first part 11) are not significantly impaired, but instead, the heat resistance and moisture resistance of the first resin layer 10 are improved, and adhesion between the first resin layer 10 and magnetic body 30 is enhanced.

FIG. 7 is a partial cross-sectional view of a coil component 1C according to a third modification.

The coil component 1C according to the third modification illustrated in FIG. 7 differs from the coil component 1B illustrated in FIG. 6 in that the it further has a second resin layer 20 positioned on the opposite side of the first resin layer 10 with respect to the magnetic body 30. Other basic configurations are the same as those of the coil component 1B illustrated in FIG. 6, so the same reference numerals are given to the same elements, and overlapping description will be omitted.

The second resin layer 20 may be made of the same material as that of the first resin layer 10. That is, the second resin layer 20 may contain the same spherical filler particles as the filler particles F1 contained in the first resin layer 10 and the same binder resin as the binder resin R1 contained in the first resin layer 10. Since the coil pattern CP need not be embedded in the second resin layer 20, the ratio of the filler particles to the binder resin can be made higher in the second resin layer 20 than in the first resin layer 10, making it possible to increase the strength of the second resin layer 20.

When the magnetic body 30 is thus sandwiched between the first and second resin layers 10 and 20, it can be protected from both sides thereof. Further, the magnetic body 30 can be attached to another member through the second resin layer 20. For example, the second resin layer 20 can be used as an adhesive layer in place of the adhesive layer 72 in FIG. 3.

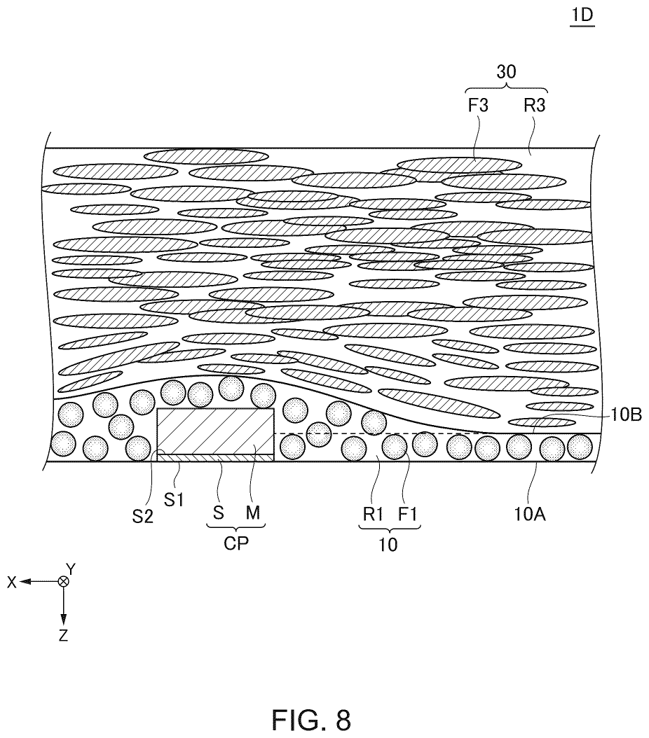

FIG. 8 is a partial cross-sectional view of a coil component 1D according to a fourth modification.

The coil component 1D according to the fourth modification illustrated in FIG. 8 differs from the coil component 1 illustrated in FIG. 4 in that the thickness of the magnetic body 30 is larger at a portion not overlapping the coil pattern CP than at a portion overlapping the coil pattern CP. Other basic configurations are the same as those of the coil component 1 illustrated in FIG. 4, so the same reference numerals are given to the same elements, and overlapping description will be omitted.

When the thickness of the magnetic body 30 is thus increased at a portion not overlapping the coil pattern CP, it is possible to achieve higher magnetic characteristics. In the example illustrated in FIG. 8, the Z-direction position of the boundary (10B) between the first resin layer 10 and magnetic body 30 at a portion not overlapping the coil pattern CP is within the height range of the coil pattern CP. This further improves magnetic characteristics.

While some embodiment of the present disclosure has been described, the present disclosure is not limited to the above embodiment, and various modifications may be made within the scope of the present disclosure, and all such modifications are included in the present disclosure.

For example, the coil component 1 illustrated in FIG. 4 and coil component 1A illustrated in FIG. 5 may include the second resin layer 20 illustrated in FIG. 7.

The technology according to the present disclosure includes the following configuration examples but not limited thereto.

A coil component according to an embodiment of the present disclosure includes: a coil pattern composed of a seed part containing resin and having first and second surfaces positioned on mutually opposite sides and a main body part made of a metal material and laminated on the second surface of the seed part; a magnetic body covering the coil pattern; and a first resin layer positioned between the coil pattern and magnetic body and containing spherical filler particles and binder resin. The coil pattern is embedded in the first resin layer such that the first surface of the seed part is exposed from the first resin layer. With this configuration, the coil pattern and first resin layer firmly adhere to each other, so that voids are unlikely to occur around the coil pattern.

In the above coil component, the thickness of the main body part may be larger than the thickness of the seed part. This can reduce the resistance value of the coil pattern.

In the above coil component, the average particle diameter of the filler particles may be less than 5 μm, and the thickness of the first resin layer at a portion between the coil pattern and magnetic body may be smaller than the thickness of the coil pattern. This can further reduce the entire thickness of the coil component.

In the above coil component, the average particle diameter of the filler particles may be equal to or more than 5 μm, and the thickness of the first resin layer at a portion between the coil pattern and magnetic body may be larger than the thickness of the coil pattern. This makes it possible to disperse the filler particles uniformly while maintaining a sufficient filling rate of the filler particles.

The above coil component may further include a second resin layer positioned on the opposite side of the first resin layer with respect to the magnetic body. This can protect the magnetic body from both sides thereof.

In the above coil component, the second resin layer may contain filler particles and binder resin. This can increase the strength of the second resin layer. Further, the magnetic body can be attached to another member through the second resin layer.

In the above coil component, the magnetic body may be formed of a ferrite sintered body, and the ferrite sintered body may be a collective body of a plurality of divided individual pieces. This can increase the permeability of the magnetic body and suppress a change in magnetic characteristics.

In the above coil component, the binder resin constituting the first resin layer may be infiltrated into at least some of gaps between the individual pieces of the ferrite sintered body. This allows the individual pieces to be fixed to one another by the binder resin, making it possible to increase the strength of the magnetic body.

In the above coil component, the magnetic body may be a magnetic resin layer containing flat magnetic powders and binder resin. This can not only facilitate processing of the coil component but also make the entire coil component flexible.

In the above coil component, the first resin layer may include a first region positioned on the magnetic body side and a second region in which the coil pattern is embedded. This enhances adhesion of the first resin layer with respect to the coil pattern and magnetic body.

In the above coil component, the magnetic resin layer may contain curing agent, and the first region may contain the same curing agent as that contained in the magnetic resin layer. This can improve the heat resistance and moisture resistance of the first resin layer.

In the above coil component, the concentration of the curing agent contained in the first region may be lower than the concentration of the curing agent contained in the magnetic resin layer. This can maintain sufficient embedding characteristics of the first resin layer.

In the above coil component, the ratio of the flat magnetic powders contained in the magnetic resin layer to the binder resin contained in the magnetic resin layer may be higher than the ratio of the filler particles contained in the first resin layer to the binder resin contained in the first resin layer. This can achieve high inductance while maintaining sufficient embedding characteristics for the coil pattern.

An IC card according to an embodiment of the present disclosure has the above-described coil component. Thus, there can be provided a thin IC card.

What is claimed is:

1. A coil component comprising:
a coil pattern having:
a seed part including resin and having first and second surfaces positioned on mutually opposite sides; and
a main body part made of a metal material and laminated on the second surface of the seed part;
a magnetic body covering the coil pattern; and
a first resin layer positioned between the coil pattern and magnetic body and including spherical filler particles and binder resin,
wherein the coil pattern is embedded in the first resin layer such that the first surface of the seed part is exposed from the first resin layer.

2. The coil component as claimed in claim 1, wherein a thickness of the main body part is larger than a thickness of the seed part.

3. The coil component as claimed in claim 1,
wherein an average particle diameter of the filler particles is less than 5 μm, and
wherein a thickness of the first resin layer at a portion between the coil pattern and magnetic body is smaller than a thickness of the coil pattern.

4. The coil component as claimed in claim 1,
wherein an average particle diameter of the filler particles is equal to or more than 5 μm, and
wherein a thickness of the first resin layer at a portion between the coil pattern and magnetic body is larger than a thickness of the coil pattern.

5. The coil component as claimed in claim 1, further comprising a second resin layer positioned on an opposite side of the first resin layer with respect to the magnetic body.

6. The coil component as claimed in claim 5, wherein the second resin layer includes filler particles and binder resin.

7. The coil component as claimed in claim 1,
wherein the magnetic body is formed of a ferrite sintered body, and
wherein the ferrite sintered body is a collective body of a plurality of divided individual pieces.

8. The coil component as claimed in claim 7, wherein the binder resin included in the first resin layer is infiltrated into at least some of gaps between the individual pieces of the ferrite sintered body.

9. The coil component as claimed in claim 1, wherein the magnetic body is a magnetic resin layer including flat magnetic powders and binder resin.

10. The coil component as claimed in claim 9, wherein the first resin layer includes a first region positioned on the magnetic body side and a second region in which the coil pattern is embedded.

11. The coil component as claimed in claim 10,
wherein the magnetic resin layer includes curing agent, and
wherein the first region includes a same curing agent as that included in the magnetic resin layer.

12. The coil component as claimed in claim 11, wherein a concentration of the curing agent included in the first region is lower than a concentration of the curing agent included in the magnetic resin layer.

13. The coil component as claimed in claim 9, wherein a ratio of the flat magnetic powders included in the magnetic resin layer to the binder resin included in the magnetic resin layer is higher than a ratio of the filler particles included in the first resin layer to the binder resin included in the first resin layer.

14. An IC card comprising a coil component,
wherein the coil component comprising:
a coil pattern having:
a seed part including resin and having first and second surfaces positioned on mutually opposite sides; and
a main body part made of a metal material and laminated on the second surface of the seed part;
a magnetic body covering the coil pattern; and
a first resin layer positioned between the coil pattern and magnetic body and including spherical filler particles and binder resin, and
wherein the coil pattern is embedded in the first resin layer such that the first surface of the seed part is exposed from the first resin layer.
